(19) United States
(12) Patent Application Publication
(10) Pub. No.: US 2004/0119155 A1
(43) Pub. Date: Jun. 24, 2004

(54) Metal wiring board and method for manufacturing the same

(76) Inventors: Takeyoshi Hisada, Hekinan-city (JP); Hirofumi Mokuya, Kariya-city (JP)

Correspondence Address: POSZ & BETHARDS, PLC, 11250 ROGER BACON DRIVE, SUITE 10, RESTON, VA, 20190, US

(21) Appl. No.: 10/729,974

(22) Filed: Dec. 9, 2003

(30) Foreign Application Priority Data
Dec. 19, 2002 (JP) 2002-368087

(51) Int. Cl. H01L 21/44; H01L 23/48

(52) U.S. Cl. 257/692; 257/690; 257/784; 438/617

(57) ABSTRACT

A metal wiring board includes a metal plate as a substrate. The metal plate is stamped in a predetermined wiring pattern including wiring portions and terminal portions. The metal plate has soldering areas prepared for electrical connection and non-soldering areas coated with solder resist on its surface.

### CROSS REFERENCE TO RELATED APPLICATION

This application is based on and incorporates herein by reference Japanese Patent Application No. 2002-368087 filed on Dec. 19, 2002.

### FIELD OF THE INVENTION

The present invention relates to a metal wiring board having a metal plate formed in a predetermined wiring pattern, a surface of which is prepared for soldering of electronic components.

### BACKGROUND OF THE INVENTION

One of commonly used metal wiring boards having specific circuit patterns is a busbar wiring board used in a relay box for a vehicle. One kind of such a board is proposed in JP-A-655971. A metal plate made of copper or aluminum is stamped or etched to provide a certain form of a busbar wiring board. The metal plate functions as electric wires and therefore the busbar wiring board provides thick wires that enable large current flow in comparison with a printed wiring board.

During solder application to the surface of the busbar wiring board, non-soldering areas of the busbar wiring board surface need to be protected from the solder application. The busbar wiring board may be insert-molded with a resin to cover the non-soldering areas with the resin. However, the busbar wiring board cannot be provided at low cost if it is manufactured by insert molding.

Furthermore, the resin creates a difference in level between a soldering area and a non-soldering area (covered area) resulting in inconvenience for soldering. The resin cannot provide precise and fine arrangements in covering the non-soldering areas. Especially, the non-soldering areas are not properly covered with the resin when electronic components with small-pitched leads (a few tenths of millimeter), such as s small outline package (SOP) or a quad flat package (QFP).

A commonly used metal base substrate is shown in FIG. 4. The substrate includes a metal base J1 made of copper or aluminum, a glass epoxy resin insulating layer J2, and a conductive foil layer J3 made of copper. Terminals are welded or soldered to the conductive foil layer J3, or inserted in holes provided in the metal base J1. The holes are filled with an insulating material after the terminals are inserted. Manufacturing of a metal wiring board using this substrate requires many steps.

### SUMMARY OF THE INVENTION

The present invention therefore has an objective to provide a metal wiring board having a metal plate processed in a predetermined wiring pattern and a surface of which is prepared for proper and cost-effective soldering of electronic components having small-pitched leads. A metal wiring board of the present invention includes a metal plate as a substrate. The metal plate is processed in a predetermined wiring pattern including wiring portions and terminal portions. A surface of the metal plate has soldering areas prepared for electrical connection and non-soldering areas coated with solder resist.

The solder resist is formed on the surface of the metal plate by solder resist printing using a mask. The solder resist printing provides more precise and fine coating on the non-soldering areas at lower cost than the insert molding with resin.

Moreover, the solder resist creates a smaller difference in level between the soldering area and the non-soldering area. Thus, soldering electronic components can be easily performed with high reliability. Electronic components having small-pitched leads are properly soldered to the metal wiring board at low cost.

The present invention has another objective to provide a method for manufacturing the metal wiring board. The method includes steps of defining the non-soldering area on the metal plate, coating the surface of the metal plate except for the non-soldering area with solder resist, and removing unnecessary portions of the metal plate to form the predetermined wiring pattern. Since the metal plate is protected from unwanted solder application and shaped in the predetermined wiring pattern, an electronic device can be directly soldered onto the metal plate.

### BRIEF DESCRIPTION OF THE DRAWINGS

The above and other objectives, features and advantages of the present invention will become more apparent from the following detailed description made with reference to the accompanying drawings. In the drawings:

FIG. 1 is a perspective view of a metal wiring board according to an embodiment of the present invention;

FIG. 2 is an enlarged view of the metal wiring board around a soldering area and a lead of the electronic device soldered to the soldering area according to the embodiment;

FIG. 3A is a top view of a metal plate after a resist printing step is completed according to the embodiment;

FIG. 3B is a top view of the metal plate after a metal plate stamping step is completed according to the embodiment; and

FIG. 4 is a cross-sectional view of a metal-based substrate according to a related art.

### DETAILED DESCRIPTION OF THE PREFERRED EMBODIMENT

The preferred embodiment of the present invention will be explained with reference to the accompanying drawings.

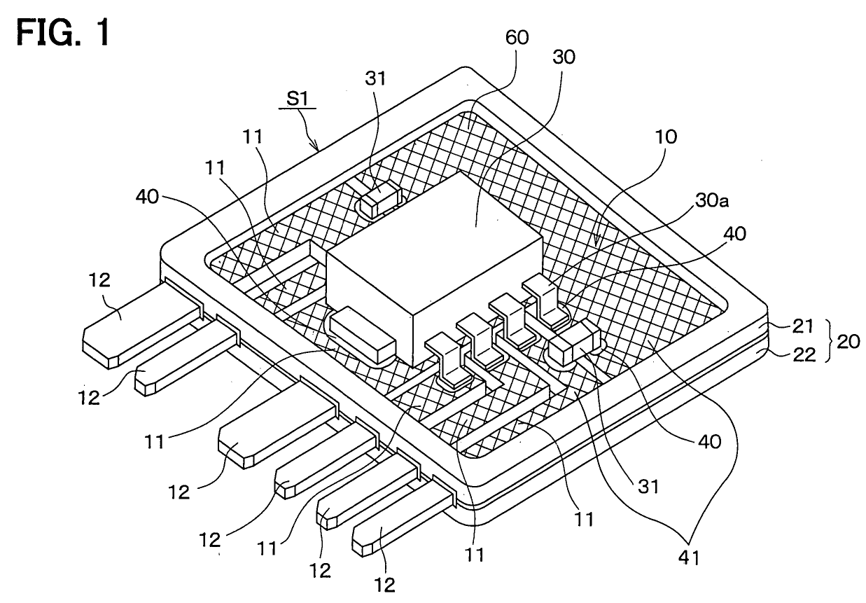

Referring to FIG. 1, a metal wiring board S1 includes a metal plate 10 as a substrate. A power component 30 and resistors 31, which are SMD components, are soldered to the metal wiring board S1. The metal plate 10 is made of copper base metal and has a thickness of equal to or more than 500 μm, for instance approximately 640 μm.

The metal plate 10 is stamped in predetermined wiring patterns including wiring portions 11 and terminal portions 12. More precisely, the metal plate 10 is a cluster of the wiring portions 11 arranged in the predetermined wiring pattern and held together with a case 20. The terminal portions 12 are provided at ends of the wiring portions 11 for connections with external devices. The metal plate 10 has a surface including soldering areas 40 that are conductive areas for electrical connection and non-soldering areas 41 that are electrically isolated areas coated with solder resist.

The wiring portions 11 are secured with the case 20 that holds edges of the metal plate 10. The case 20 is made of an insulating material, such as a ceramic or a resin, and constructed of an upper case 21 and a lower case 22. The wiring portions 11 are sandwiched between the upper case 21 and the lower case 22 and secured when the upper case 21 and the lower case 22 are engaged or glued together. The terminal portions 12 project outside the case 20.

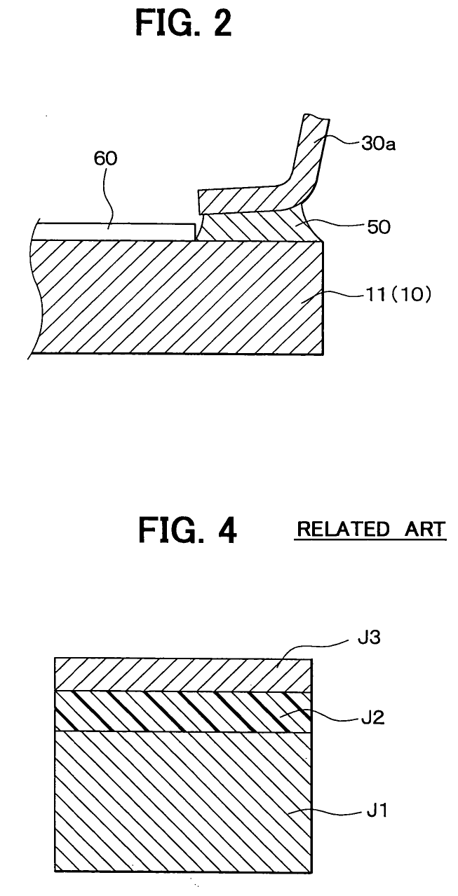

The power component 30 and the resistors 31 are small outline package (SOP) surface mount device (SMD) such as a power MOS transistor. The power component 30 has leads (outer leads) 30a with a small pitch, for instance a few tenths of millimeter. The leads 30a and the resistors 31 are solder to the soldering areas 40 of the metal wiring board S1. Each lead 30a is soldered to the respective soldering areas 40 as shown in FIG. 2 and connected to the wiring portions 11 of the metal wiring board S1 via solder 50. The power component 30 and the resistors 31 are mounted as they bridge adjacent wiring portions 11.

The surface of the metal wiring board S1 is coated with solder resist 60 except for soldering areas 40 and the terminal portions 12, which are conductive portions. Areas coated with solder resist 60 are electrically isolated areas as indicated with cross-hatching and referred to as non-soldering areas 41. The solder resist 60 is formed on the surface by solder resist printing, in which a screen printing method using a mask is applied. The screen printing method is commonly used for circuit pattern printing performed on a glass epoxy substrate or a paper phenol substrate. The metal wiring board S1 is protected from unwanted soldering application during an application of the solder 50 to the soldering areas 40 by coating the surface with solder resist.

Since the solder resist 60 is formed by the solder resist printing, the non-soldering areas 41 are more accurately coated with the solder resist 60 in comparison with the insert molding. Moreover, the screen printing provides precise coating on the surface at lower cost than the insert molding.

The insulating layer formed by the solder resist is thinner than that formed by a resin. Therefore, the surface of the metal wiring board S1 is maintained closer to flat and that makes soldering easier. With this configuration, the solder 50 is properly applied to the leads 30a and the resistors 31 at low cost.

In the metal wiring board S1, the wiring portions 11 and the terminal portions 12 are provided by stamping the metal plate 10 in the predetermined wiring pattern. Thus, the metal wiring board S1 requires less manufacturing steps than the substrate shown in FIG. 4 and therefore the terminal portions 12 are provided at lower cost. Furthermore, proper electrical connection between the metal wiring board S1 and external devices is ensured via the terminal portions 12 that are not coated with solder resist.

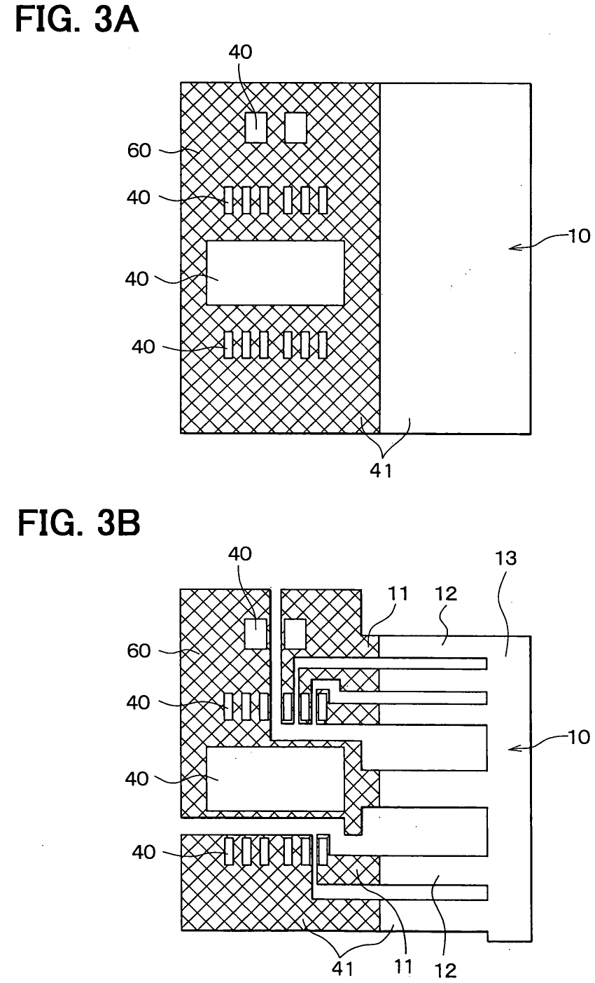

A method for manufacturing the metal wiring board S1 will be discussed below referring to FIGS. 3A and 3B.

The solder resist 60 is formed on the surface of the metal plate 10 except for the soldering areas 40 and the terminal portions 12 by the solder resist printing using a mask as shown in FIG. 3A. This is referred to as a solder resist printing process. Unnecessary parts of the metal plate 10 are stamped and the wiring portions 11 and terminal portions 12 are formed in predetermined wiring patterns as shown in FIG. 3B. This is referred to as a metal plate stamping process. The wiring portions 11 are connected together via a frame portion 13.

The wiring portions 11 are held between the upper case 21 and the lower case 22, and then the frame portion 13 is removed. When this process is completed, the metal wiring board S1 is finished. Solder is applied to the soldering areas 40 by the solder printing method. The power component 30 and the resistors 31 are solder to the metal wiring board S1 by reflow soldering. The metal wiring board with the power component 30 and the resistors 31 shown in FIG. 1 is completed.

The present invention should not be limited to the embodiment previously discussed and shown in the figures, but may be implemented in various ways without departing from the spirit of the invention. For example, other surfaces of the metal plate 10 may be coated with the solder resist. Electronic components may be mounted on a surface opposite to the surface on which the power component 30 and the resistors 31 are mounted. In this case, areas in which solder is not applied are also coated with solder resist. The metal plate 10 may be fixed by means other than sandwiching between the upper case 21 and the lower case 22 of the case 20. For instance, each wiring portion 11 can be bonded to a plate or a case made of an insulating material, such as a ceramic and a resin.

What is claimed is:

1. A metal wiring board comprising a metal plate as a substrate, wherein:
the metal plate is processed in a predetermined wiring pattern;
the metal plate has a surface including a soldering area and a non-soldering area;
the soldering area is a conductive area prepared for electrical connection; and
the non-soldering area is an electrically isolated area coated with solder resist.

2. The metal wiring board according to claim 1, wherein the predetermined wiring pattern includes a wiring portion that functions as an electrical wire.

3. The metal wiring board according to claim 1, wherein the predetermined wiring pattern further includes a terminal portion for electrical connection with an external device.

4. The metal wiring board according to claim 1, wherein the processing of the metal plate is performed by stamping the metal plate.

5. The metal wiring board according to claim 1, wherein the solder resist coating on the non-soldering area is performed by solder resist printing.

6. The metal wiring board according to claim 1, wherein the wiring portions are held by a resin case at ends thereof.

7. The metal wiring board according to claim 1, wherein the soldering area is prepared for soldering of a surface mount device having leads with a small pitch.

8. The metal wiring board according to claim 8, wherein:
the metal plate includes a plurality of soldering areas; and
the soldering areas are arranged so that a surface mount device bridges adjacent electrical wiring portions when soldered.

9. A method for manufacturing the metal wiring board claimed in claim 1, comprising:
defining the non-soldering area on the metal plate;
coating the surface of the metal plate with solder resist except for the non-soldering area; and
removing unnecessary portions of the metal plate to form the predetermined wiring pattern.

10. The method for manufacturing the metal wiring board according to claim 10, further comprising processing the metal plate to provide the terminal portion.

11. The method for manufacturing the metal wiring board according to claim 10, wherein the coating step is performed by solder resist printing.

12. The method for manufacturing the metal wiring board according to claim 10, the removing step is performed by stamping.

13. The method for manufacturing the metal wiring board according to claim 11, wherein the terminal portion are connected together at ends thereof with a frame portion, further comprising:
holding the electrical wiring portions by a case; and
removing the frame portion.
